(19) United States
(12) Patent Application Publication
(10) Pub. No.: US 2025/0164873 A1
(43) Pub. Date: May 22, 2025

(54) PHOTORESIST COMPOSITION AND METHOD OF MANUFACTURING INTEGRATED CIRCUIT DEVICE USING THE SAME

(71) Applicant: SAMSUNG ELECTRONICS CO., LTD., Suwon-si (KR)

(72) Inventors: Yonghoon Moon, Suwon-si (KR); Honggu Im, Suwon-si (KR); Suk Koo Hong, Suwon-si (KR); Hana Kim, Suwon-si (KR); Sungan Do, Suwon-si (KR)

(21) Appl. No.: 18/776,692

(22) Filed: Jul. 18, 2024

(30) Foreign Application Priority Data
Nov. 20, 2023 (KR) 10-2023-0161441

(51) Int. Cl. G03F 7/004; G03F 7/38; H01L 21/768

(52) U.S. Cl. CPC G03F 7/0042; G03F 7/38; H01L 21/76838

(57) ABSTRACT

A photoresist composition and a method of manufacturing an integrated circuit device using the photoresist composition includes an organometallic compound including a central metal and at least one organic ligand bonded to the central metal, and a solvent, wherein the at least one organic ligand included in the organometallic compound includes an ylide group including an atom with a formal charge of −1 coordinately bonded to the central metal and a hetero atom with a formal charge of +1 bonded to the atom with a formal charge of −1.

### CROSS-REFERENCE TO RELATED APPLICATION

This application claims priority to Korean Patent Application No. 10-2023-0161441, filed in the Korean Intellectual Property Office on Nov. 20, 2023, the disclosure of which is incorporated by reference herein in its entirety.

### BACKGROUND

Due to the development of electronic technology, down-scaling of integrated circuit devices is rapidly progressing. Accordingly, a photolithography process that is advantageous for implementing fine patterns is desired.

### SUMMARY

In general, in some aspects, the present disclosure is directed toward a photoresist composition having improved process stability by suppressing changes over time in a photolithography process for manufacturing integrated circuit devices and provide improved etch resistance and resolution.

According to some aspects, the present disclosure is directed to a method of manufacturing an integrated circuit device that improves process stability by suppressing changes over time in the photolithography process and improves the dimensional precision of patterns to be formed by providing improved etch resistance and resolution.

According to some aspects, the present is directed to a photoresist composition including an organometallic compound including a central metal and at least one organic ligand bonded to the central metal, and a solvent, wherein the at least one organic ligand included in the organometallic compound includes an ylide group including an atom with a formal charge of −1 coordinately bonded to the central metal and a hetero atom with a formal charge of +1 bonded to the atom with a formal charge of −1.

According to some aspects, the present disclosure is directed to a photoresist composition including an organometallic compound including a central metal and a plurality of organic ligands bonded to the central metal, an organic ligand precursor, and a solvent, wherein the plurality of organic ligands included in the organometallic compound is a substituted or unsubstituted C1 to C30 aliphatic hydrocarbon group, or a substituted or unsubstituted C6 to C30 aromatic hydrocarbon group covalently or coordinately bonded to the central metal, and the organic ligand precursor is a C1 to C30 aliphatic hydrocarbon group including a first atom with a formal charge of −1 capable of a ligand substitution reaction with at least one of the plurality of organic ligands bonded to the central metal, and a second atom that is a hetero atom with a formal charge of +1 bonded to the first atom, or a substituted or unsubstituted C6 to C30 aromatic hydrocarbon group including the first atom and the second atom.

According to some aspects, the present disclosure is directed to a method of manufacturing an integrated circuit device, the method including forming a photoresist film on a substrate using a photoresist composition including a central metal, an organometallic compound including a plurality of organic ligands bonded to the central metal, and a solvent, exposing a first region that is a part of the photoresist film, forming a metal structure network in the first region by inducing a desorption reaction of some of the plurality of organic ligands from the organometallic compound in the first region bybound baking the photoresist film including the exposed first region and by inducing a condensation reaction of a hydroxyl (OH) functional group generated at the site where some of the plurality of organic ligands among the organometallic compounds are desorbed, and forming a photoresist pattern including the metal structure network by developing the photoresist film on which the metal structure network is formed, wherein, in the forming of the photoresist film, at least one of the plurality of organic ligands includes an ylide group including a first atom and a second atom, wherein the first atom has a formal charge of −1 and is coordinated to the central metal, and the second atom is a heteroatom with a formal charge of +1 and is bonded to the first atom.

### BRIEF DESCRIPTION OF THE DRAWINGS

Example implementations will be more clearly understood from the following detailed description, taken in conjunction with the accompanying drawings.

FIG. 1 is a flowchart illustrating an example of a method of manufacturing an integrated circuit device according to some implementations.

FIGS. 2A-2F are cross-sectional views illustrating an example of a method of manufacturing an integrated circuit device according to some implementations.

### DETAILED DESCRIPTION

Hereinafter, example implementations will be explained in detail with reference to the accompanying drawings.

Photoresist compositions may include an organometallic compound and a solvent. According to some implementations, the organometallic compound may include a central metal and at least one organic ligand bonded to the central metal. For example, the organometallic compound may include a central metal and at least one organic ligand coordinately or covalently bonded to the central metal.

In the photoresist composition, the central metal included in the organometallic compound may include at least one metal element. The at least one metal element may include a metal atom. In some implementations, the center metal may include at least one metal element selected from Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, and Fe, but the present disclosure is not limited to the above examples.

In the photoresist composition, the organic ligand included in the organometallic compound may include C1 to C30 aliphatic hydrocarbon group including a first atom with a formal charge of −1 that binds to the central metal and a second atom that is a heteroatom with a formal charge of +1 and is bonded to the first atom with a formal charge of −1, or a substituted or unsubstituted C6 to C30 aromatic hydrocarbon group including the first atom and the second atom.

In the present disclosure, the C1 to C30 aliphatic hydrocarbon group including the first atom with a formal charge of −1 and a second atom that is a heteroatom with a formal charge of +1 and is bonded to the first atom with a formal charge of −1, or the substituted or unsubstituted C6 to C30 aromatic hydrocarbon group including the first atom and the second atom may be referred to as a ylide group. The ylide group may include, for example, phosphorus ylide, sulfur ylide, or nitrogen ylide. In present specification, an organic ligand including the ylide group may be referred to as a “ylide ligand.”

In some implementations, the organometallic compound may be represented by Formula 1 below.

M(A¹¹)ₐ(A₁₂)_{b}(A¹³)_{c}(B¹¹)_{d} [Formula 1]

In Formula 1, M represents Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
A¹¹, A¹², and A¹³ each represents a substituted or unsubstituted C1 to C30 aliphatic hydrocarbon group or a substituted or unsubstituted C6 to C30 aromatic hydrocarbon group that are covalently or coordinately bonded to the M,
B¹¹ represents a C1 to C30 aliphatic hydrocarbon group including the first atom with a formal charge of −1 that coordinates with the M and the second atom that is at least one hetero atom with a formal charge of +1 that bonds to the first atom with a formal charge of −1 or a substituted or unsubstituted C6 to C30 aromatic hydrocarbon group including the first atom and the second atom, that is, the ylide group described above, and
a, b, c, and d are each independently integers greater than 0 and less than or equal to 4, and a+b+c+d is less than or equal to 4.

In some implementations, the organometallic compound may be represented by Formula 2 below.

M(A¹¹)ₐ(A¹²)_{b}(A¹³)_{c}(A¹⁴)_{d} [Formula 2]

In Formula 2, M represents Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
A¹¹, A¹², A¹³, and A¹⁴ each represents a substituted or unsubstituted C1 to C30 aliphatic hydrocarbon group or a substituted or unsubstituted C6 to C30 aromatic hydrocarbon group that are covalently or coordinately bonded to M.
a, b, c, and d are each independently integers greater than 0 and less than or equal to 4, and a+b+c+d is less than or equal to 4.

As used herein, unless otherwise defined, the term “substituted” denotes that at least one hydrogen bonded to carbon is replaced with a substituent, or at least one carbon atom is replaced with a heteroatom including group. The substituent may include, for example, a halogen element, a hydroxy group, an aldehyde group, a carboxyl group, an amino group, a cyano group, an isocyanate group, a thiol group, a sulfonic acid group, a phosphoric acid group, a salt thereof, C1 to C20 alkyl, C1 to C20 cycloalkyl, C2 to C20 alkenyl, C1 to C20 alkoxy, C2 to C20 alkenoxy, C6 to C30 aryl, C6 to C30 aryloxy, C7 to C30 alkylaryl, or a C7 to C30 alkylaryloxy group. The hetero element-including group may be, for example, —O—, —C(═O)—O—, —O—C(═O)—, —C(═O)—, —O—C(═O)—O—, —C(═O)—NH—, —NH—, —S—, —S(═O)₂—, or —S(═O)₂—O—.

In some implementations, A¹¹, A¹², A¹³, and A¹⁴ may each not include the ylide group described above.

In some implementations, A¹¹, A¹², A¹³, and A¹⁴ are each a substituted or unsubstituted C1 to C30 aliphatic hydrocarbon group covalently bonded to M, or a substituted or unsubstituted C6 to C30 aromatic hydrocarbon group covalently bonded to M. For example, hydrogen or carbon included in A¹¹, A¹², A¹³, and A¹⁴ may be covalently bonded to M. Hereinafter, when A¹¹, A¹², A¹³, and A¹⁴ are each hydrocarbon groups covalently bonded to M, A¹¹, A¹², A¹³, and A¹⁴ may be referred to as R¹¹, R¹², R¹³, and R¹⁴, respectively.

In some implementations, R¹¹, R¹², R¹³, and R¹⁴ may each be a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C₃₀ heteroaryl group, a substituted or unsubstituted C7 to C30 arylalkyl group, or a substituted or unsubstituted phenyl group.

In some implementations, R¹¹, R¹², R¹³, and R¹⁴ may include a methyl group, an ethyl group, a propyl group, a butyl group, an isopropyl group, a tertiary butyl group, a tertiary amyl group, a secondary butyl group, a cyclopropyl group, a cyclobutyl group, a cyclopentyl group, or a cyclohexyl group.

In some implementations, R¹¹, R¹², R¹³, and R¹⁴ may include an aromatic ring. The aromatic ring may be a single aromatic ring such as benzene; a heteroaryl group such as pyridine, pyrimidine, thiophene, etc., or a condensed aryl group such as quinoline, isoquinoline, naphthalene, anthracene, and phenanthrene.

In some implementations, R¹¹, R¹², R¹³, and R¹⁴ may each include an acid group selected from a hydroxyl group, a sulfonate group, a carboxyl group, and a phosphonate group.

In some implementations, R¹¹, R¹², R¹³, and R¹⁴ may each include at least one selected from the following structural units. In the following structures, * is a binding position.

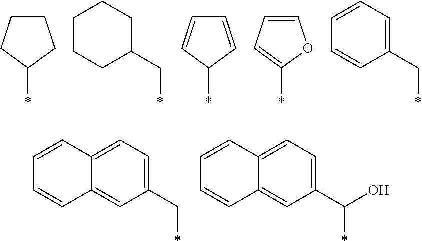

In some implementations, R¹¹, R¹², R¹³, and R¹⁴ may each include at least one structure selected from the following structural units.

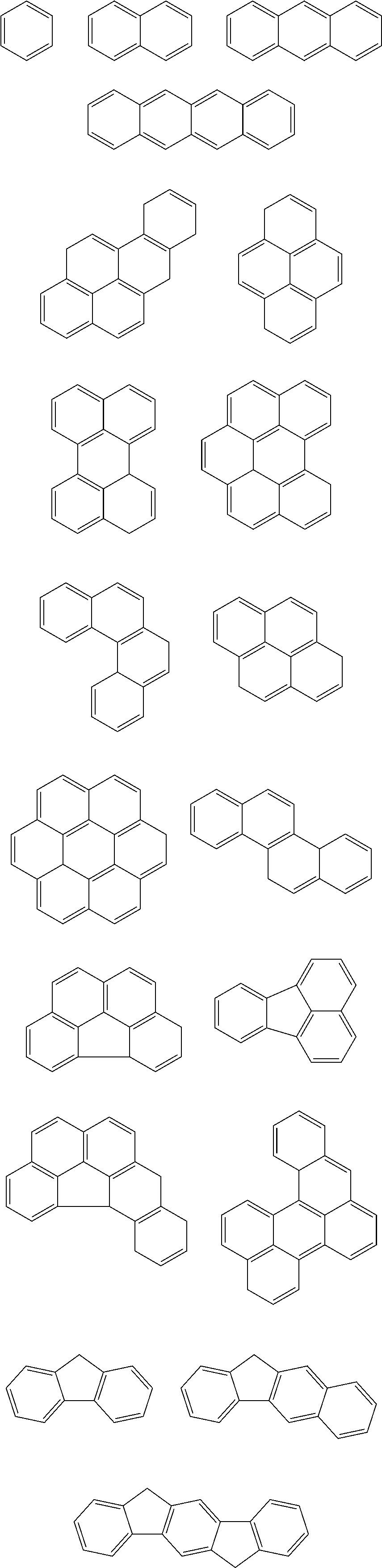

In some implementations, R¹¹, R¹², R¹³, and R¹⁴ may each have the same structure. In some other embodiments, at least one selected from R¹¹, R¹², R¹³, and R¹⁴ may have a different structure from the others.

In some implementations, A¹¹, A¹², A¹³, and A¹⁴ may each include at least one hetero atom and may be a substituted or unsubstituted C1 to C30 aliphatic hydrocarbon group or a substituted or unsubstituted C6 to C30 aromatic hydrocarbon group that are coordinated to the M. For example, at least one hetero atom included in A¹¹, A¹², A¹³, and A¹⁴ may coordinate to M. Hereinafter, when A¹¹, A¹², A¹³, and A¹⁴ each include at least one hetero atom as described above and are a hydrocarbon group coordinated to the M, A¹¹, A¹², A¹³, and A¹⁴ may be referred to as X¹¹, X¹², X¹³, and X¹⁴, respectively.

In some implementations, X¹¹, X¹², X¹³, and X¹⁴ may each be R²¹—O—*, R²²—C(═O)—O—*, R²³—O—C(═O)—*, R²⁴—O—C(═O)—O—*, R²⁵—N(R²⁶)—*, R²⁷—S—*, R²⁸—S(═O)₂—*, or R²⁹—S(═O)₂—O—*. Wherein, * is a binding site with M, and R²¹, R²², R²³, R²⁴, R²⁵, R²⁶, R²⁷, R²⁸, and R²⁹ may each be independently hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

In some implementations, X¹¹, X¹², X¹³, and X¹⁴ may each include a hydrocarbyl group substituted with at least one heteroatom functional group including an oxygen atom, a nitrogen atom, a halogen atom, cyano, thio, silyl, ether, carbonyl, ester, nitro, amino, or any combination thereof. The halogen element may include F, Cl, Br, or I.

In some implementations, X¹¹, X¹², X¹³, and X¹⁴ may each include an acid group selected from a hydroxyl group, a sulfonate group, a carboxyl group, and a phosphonate group.

In some implementations, X¹¹, X¹², X¹³, and X¹⁴ may each include a CF₃COO-ligand, a CF₃SO₃-ligand, a CF₂CF₂SO₃-ligand, a CF₃CF₂(CF₃)₂CO-ligand, a CF₃SO₂-ligand, a para-toluenesulfonyl ligand, or a diethyl phosphate ligand.

In some implementations, X¹¹, X¹², X¹³, and X¹⁴ may each include an aromatic ring, a heteroaromatic ring, or any combination thereof. The aromatic ring may be a single aromatic ring such as benzene; a heteroaryl group such as pyridine, pyrimidine, thiophene, etc.; or a condensed aryl group such as quinolone, isoquinoline, naphthalene, anthracene, and phenanthrene, etc. The heteroaryl group and the condensed aryl group may include at least one hetero atom selected from oxygen (O), sulfur(S), and nitrogen (N).

In some implementations, X¹¹, X¹², X¹³, and X¹⁴ may each include a polydentate ligand. The polydentate ligand may include a bidentate ligand including two atoms capable of coordination, a tridentate ligand including three atoms capable of coordination, or a tetradentate ligand including four atoms capable of coordination, but is not limited thereto. For example, the polydentate ligand may include quinoline, β-diketonate, ethylenediaminetetraacetic acid (EDTA), 2,2′-bis(diphenylphosphino)-1,1′-binaphthyl (BINAP), salen: (2,2)ethylenebis (nitrilomethylidene)diphenol), norbornene dicarboxylic acid, camphoric acid, and a structure selected from derivatives thereof, but is not limited thereto.

In some implementations, X¹¹, X¹², X¹³, and X¹⁴ may each have the same structure. In some other example embodiments, at least one selected from X¹¹, X¹², X¹³, and X¹⁴ may have a different structure from the others.

In some implementations, A¹¹ may be any one selected from R¹¹ or X¹¹, A¹² may be any one selected from R¹² or X¹², A¹³ may be any one selected from R¹³ or X¹³, and A¹⁴ may be any one selected from R¹⁴ or X¹⁴. In some embodiments, the organometallic compound may be expressed as MR¹¹X¹²X¹³B¹¹ (MRX₂B) or MR¹¹R¹²X¹³B¹¹ (MR₂XB) In some other embodiments, the organometallic compound may be expressed as MR¹¹X¹²X¹³X¹⁴ (MRX₃), MR¹¹R¹²X¹³X¹⁴ (MR₂X₂) or MR¹¹R¹²R¹³X¹⁴ (MR₃X). At this time, R may be a substituted or unsubstituted C1 to C30 aliphatic hydrocarbon group or a substituted or unsubstituted C6 to C30 aromatic hydrocarbon group that are covalently bonded to the M including R¹¹, R¹², R¹³, and R¹⁴. X may be a substituted or unsubstituted C1 to C30 aliphatic hydrocarbon group or a substituted or unsubstituted C6 to C30 aromatic hydrocarbon group that are covalently bonded to the M that includes X¹¹, X¹², X¹³ and X¹⁴ and at least one hetero atom.

In some implementations, B¹¹ may include a ylide group including pyridinium of [C₅H₅NH]⁺, that is, a pyridinium ylide group. For example, B¹¹ may be R³¹—C(═O)—N— ([C₅H₅NH]⁺)—*, R³²—S(═O)₂—N⁻([C₅H₅NH]⁺)—*, R³³—C(═O)—C⁻([C₅H₅NH]⁺)—*, or [C₅H₅NH]⁺—O⁻—*. Wherein, * is a binding site with M, and R³¹, R³², and R³³ may each be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

In some implementations, B¹¹ may be R³⁴-Ht⁺(R³⁵)(R³⁶)—C⁻(R³⁷)—*. Wherein * is a binding site with M, Ht is a hetero atom such as nitrogen (N), sulfur(S), or phosphorus (P), and R³⁴, R³⁵, R³⁶, and R³⁷ may each be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

In some implementations, B¹¹ may include an aromatic ring, a heteroaromatic ring, or any combination thereof at a terminal. The aromatic ring may be a single aromatic ring such as benzene; a heteroaryl group such as pyridine, pyrimidine, thiophene, etc.; or a condensed aryl group such as quinolone, isoquinoline, naphthalene, anthracene, and phenanthrene, etc., The heteroaryl group and the condensed aryl group may include at least one hetero atom selected from oxygen (O), sulfur(S), and nitrogen (N).

In some implementations, B¹¹ may include a reactive group at a terminal. For example, the reactive group may include an acid group selected from a hydroxyl group, a sulfonate group, a carboxyl group, and a phosphonate group, but is not limited thereto.

In some implementations, B¹¹ may include a sterically bulky functional group at the terminal. For example, B¹¹ may include a sterically bulky functional group at the terminal like a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group, but is not limited thereto.

In some implementations, when B¹¹ includes the above-described pyridinium ylide group, B¹¹ may include a bulky functional group that binds to the pyridine of the pyridinium ylide group. Through combining B¹¹ with the bulky functional group, a reaction in which the central metal reacts with moisture to form a hydroxy group (OH group) may be suppressed, thereby providing a more stable organometallic compound. Also, the bulky functional group may be separated from the organometallic compound through a decomposition reaction of the ylide ligand in an exposure process, thereby preventing critical dimension (CD) distribution deterioration of a pattern.

For example, B¹¹ may include at least one structure selected from the following structures.

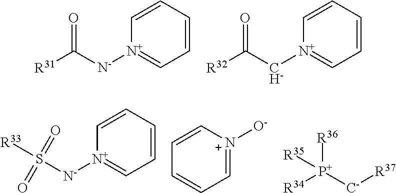

In the above structures, as described above, R³¹, R³², R³³, R³⁴, R³⁵, R³⁶, and R³⁷ may each include hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

The first atom having a formal charge of −1 in B¹¹ may have at least one binding site capable of binding to the central metal. In some embodiments, B¹¹1 may include a monodentate ligand. In some other embodiments, B¹¹ may include a polydentate ligand. The polydentate ligand may be a bidentate ligand including two atoms capable of coordination, a tridentate ligand including three atoms capable of coordination, or a tetradentate ligand including four atoms capable of coordination, but is not limited thereto.

In some implementations, when B¹¹ includes a pyridinium ylide group, B¹¹ may be a bidentate ligand including an atom that is coordinately bonded to an ortho, meta, or para position of pyridinium included in the pyridinium ylide group. For example, B¹¹ may be a bidentate ligand including pyridine or thiophene bonded to the ortho, meta, or para position of the pyridinium. In some other embodiments, B¹¹ may be a tridentate ligand including an ester group.

For example, B¹¹ may include at least one structure selected from the following structures.

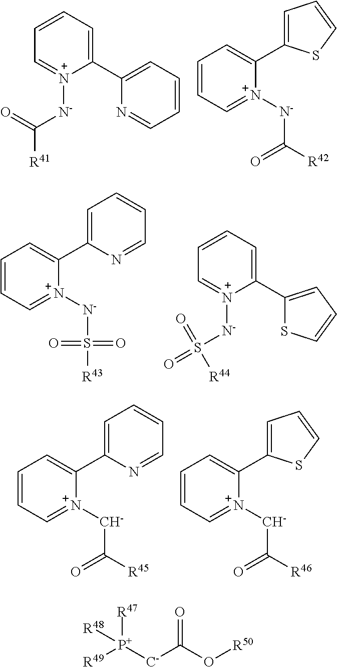

In the above structures, R⁴¹, R⁴², R⁴³, R⁴⁴, R⁴⁵, R⁴⁶, R⁴⁷, R⁴⁸, R⁴⁹, and R⁵⁰ may each include hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

The organometallic compound may have a composition of M(A¹¹)ₐ(A¹²)_{b}(A¹³)_{c}(B¹¹)_{d} (MA₃B) of Formula 1 or a composition of M(A¹¹)ₐ(A¹²)_{b} (A¹³)_{c}(A¹⁴)_{d} (MA₄) of Formula 2, but it is not limited thereto, and may have a composition of M(A¹¹)ₐ(A¹²)_{b}(B¹¹)_{c}(B¹²)_{d} (MA₂B₂), M(A¹¹)ₐ(B¹¹)_{b}(B¹²)_{c}(B¹³)_{d} (MAB₃), or M(B¹¹)ₐ(B¹²)_{b}(B¹³)_{c}(B¹⁴)_{d} (MB₄). At this time, A may be a substituted or unsubstituted C1 to C30 aliphatic hydrocarbon group or a substituted or unsubstituted C6 to C30 aromatic hydrocarbon group that covalently or coordinately bonded to M including A¹¹, A¹², A¹³, and A¹⁴, and B may be a C1 to C30 aliphatic hydrocarbon group including a first atom with a formal charge of −1 that coordinates with the M including B¹¹, B¹², B¹³, and B¹⁴ and a second atom that is a heteroatom with a formal charge of +1 bonded to the first atom with a formal charge of −1 or a substituted or unsubstituted C6 to C30 aromatic hydrocarbon group including the first atom and the second atom, that is, the above-mentioned ylide group. a, b, c, and d are each independently integers greater than 0 and less than or equal to 4, and a+b+c+d is less than or equal to 4.

In some implementations, among a total weight of the photoresist composition, a content of the organometallic compound may be in a range from about 0.1 wt % to about 20 wt %. In some embodiments, the content of the organometallic compound may be in a range from about 0.1 wt % to about 15 wt %, from about 0.1 wt % to about 10 wt %, or from about 0.1 wt % to about 5 wt %. If the content of the organometallic compound is excessively high, there is a risk that pattern stability may deteriorate due to crosslinking reaction being concentrated on an exposed surface. Conversely, if the content of the organometallic compound is excessively low, the organometallic compound may not form a sufficient amount of reactive groups and/or radicals, which may reduce pattern precision.

In the photoresist composition according to some implementations, the central metal may be included in an amount of about 0.1 wt % to about 5 wt % based on the total weight of the photoresist composition, but is limited thereto.

The organometallic compound included in the photoresist composition according to the embodiments may be obtained by purchasing a commercially available product or by synthesizing it from a well-known precursor using a method known to those skilled in the art.

In some implementations, the photoresist composition according an embodiment may further include an organic ligand precursor. The organic ligand precursor may have a structure capable of forming a coordination complex with the central metal. That is, the organic ligand precursor may have a structure in which there is at least one binding site with the central metal.

The organic ligand precursor may include a C1 to C30 aliphatic hydrocarbon group including a first atom with a formal charge of −1 that may provide a binding site to the central metal and a second atom that is a hetero atom with a formal charge of +1 bonded to the first atom or a substituted or unsubstituted C6 to C30 aromatic hydrocarbon group including the first atom and the second atom, that is, the ylide group described above.

In other words, the organic ligand precursor may be a compound that exists independently by being stabilized through resonance and delocalization in a state that the ylide group is separated from the central metal, rather than in a state that the ylide group is bonded to the central metal, such as B¹¹, B¹², B¹³, and B¹⁴.

In example embodiments, the organic ligand precursor may include R⁵¹—C(═O)—N—([C₅H₅NH]⁺), R⁵²—S(═O)₂—N—([C₅H₅NH]⁺), R⁵³—C(═O)—C— ([C₅H₅NH]⁺), or [C₅H₅NH]⁺—O⁻. Wherein R⁵¹, R⁵², and R⁵³ may each be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

In some implementations, the organic ligand precursor may include R⁵⁴-Ht⁺(R⁵⁵) (R⁵⁶)—C—(R⁵⁷). Wherein Ht may be a hetero atom such as nitrogen (N), sulfur(S), or phosphorus (P), and R⁵⁴, R⁵⁵, R⁵⁶, and R⁵⁷ may each be hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

The organic ligand precursor may form a coordination complex by binding to the central metal through a ligand substitution reaction with the ligand bonded to the central metal. For example, in an organometallic compound including A¹¹, A¹², A¹³, and/or A¹⁴, the organic ligand precursor may form an organometallic compound including B¹¹, B¹², B¹³, and/or B¹⁴ through a ligand substitution reaction with A¹¹, A¹², A¹³, and/or A¹⁴

In the photoresist composition according to some implementations, a molar ratio of the organic ligand precursor to the organometallic compound may be in a range from about 0.01 to about 10, but is not limited thereto.

In some implementations, the photoresist composition may further include a photoinitiator. The photoinitiator may be configured to generate an acid or radical by absorbing first light. The photoinitiator may generate an acid or radical by absorbing the first light in an exposed region of the photoresist film after the photoresist film obtained from the photoresist composition is exposed to the first light. The acid or radical generated from the photoinitiator may react with the organic ligand of the organometallic compound and induce a dissociation reaction of the organic ligand. Accordingly, when the photoinitiator is included in the photoresist composition according to some implementations, the desorption of the organic ligand from the organometallic compound may occur by the acid or radical generated from the photoinitiator, and a cross-linking reaction between adjacent molecules may occur during a bake process.

When the photoinitiator is included in the photoresist composition according to the embodiments, the photoinitiator may compensate for the relatively low reactivity of the organometallic compound when the photoresist film obtained from the photoresist composition is exposed to light, and In addition, the sensitivity to light in the exposed region of the photoresist film may be adjusted depending on the content of the photoinitiator. In particular, in the exposed region of the photoresist film, the photoinitiator may induce a photoreaction limited to the exposed region of the photoresist film by promoting a ligand dissociation reaction in the organometallic compound using an acid or radical.

The photoinitiator may include a photoacid generator (PAG) configured to generate acid by exposure, a photoradical generator (PRG) configured to generate radicals by exposure, or any combination of the PAG and the PRG.

The PAG may generate acid when exposed to any light selected from a KrF excimer laser (248 nm), ArF excimer laser (193 nm), F2 excimer laser (157 nm), and EUV laser (13.5 nm). In example embodiments, the PAG may include triarylsulfonium salts, diaryliodonium salts, sulfonates, or a mixture thereof. For example, the PAG may include, triphenylsulfonium triflate, triphenylsulfonium antimonate, diphenyliodonium triflate, diphenyliodonium antimonate, methoxydiphenyliodonium triflate, di-t-butyldiphenyliodonium triflate), 2,6-dinitrobenzyl sulfonates, pyrogallol tris(alkylsulfonates)), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or any combination thereof, but is not limited thereto.

When the PRG is exposed to any light selected from a KrF excimer laser (248 nm), ArF excimer laser (193 nm), F2 excimer laser (157 nm), and EUV laser (13.5 nm), the PRG absorbs the light and generates radicals, and thus, polymerization of an organometallic compound included in the photoresist composition according to the embodiments may be initiated. In some implementations, the PRG may include an acylphosphine oxide-based compound, an oxime ester-based compound, etc.

Examples of the acylphosphine oxide-based compounds may include 2,4,6-trimethylbenzoyl-diphenylphosphine oxide, bis(2,4,6-trimethylbenzoyl)-phenylphosphine oxide), bis(2,6-dimethoxybenzoyl)-(2,4,4-trimethylpentyl)phosphine oxide, etc.

Examples of the oxime ester-based compound may include 1-phenylpropane-1,2-dione-2-(O-ethoxycarbonyl) oxime, 1-phenylbutane-1,2-dione-2-(O-methoxycarbonyl) oxime, 1,3-diphenylpropane-1,2,3-trione-2-(O-ethoxycarbonyl) oxime, 1-[4-(phenylthio)phenyl]octane-1,2-dione-2-(O-benzoyl) oxime, 1-[4-[4-(carboxyphenyl)thio]phenyl]propane-1,2-dione-2-(O-acetyl) oxime, 1-[9-ethyl-6-(2-methylbenzoyl)-9H-carbazol-3-yl]ethanone-1-(O-acetyl) oxime, [9-ethyl-6-[2-methyl-4-[1-(2,2-dimethyl-1,3-dioxolane-4-yl)methyloxy]benzoyl]-9H-carbazol-3-yl]ethanone-1-(O-acetyl) oxime, etc.

In some implementations, commercially available products (BASF product, brand name) such as IRGACURE 651, IRGACURE 184, IRGACURE 1173, IRGACURE 2959, IRGACURE 127, IRGACURE 907, IRGACURE 369, IRGACURE 379, IRGACURE TPO, IRGACURE 819, IRGACURE OXE01, IRGACURE OXE02, IRGACURE MBF, IRGACURE 754 may be used as the PRG.

The resist composition, according to some implementations, may not include the photoinitiator, may include only a single material selected from the PAG and the PRG as the photoinitiator, or may include at least two substances selected from the PAG and the PRG. When the photoinitiator is included in the photoresist composition according to the embodiments, the photoinitiator may be included in an amount in a range from about 0.02 wt % to about 10 wt % based on the total amount of the organometallic compound, but is not limited thereto.

A solvent included in the photoresist composition may include an organic solvent. The organic solvent may include at least one of ether, alcohol, glycol ether, aromatic hydrocarbon compound, ketone, and ester, but is not limited thereto. For example, the organic solvent may include ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbon (MIBC)), hexanol, 1-methoxy-2-propanol, 1-ethoxy-2-propanol, ethylene glycol, propylene glycol, heptanone, Propylene carbonate, butylene carbonate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetic acid, ethyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, gamma-butyrolactone, methyl-2-hydroxyisobutyrate, methoxybenzene, n-butyl acetate, 1-methoxy-2-propyl acetate, methoxyethoxy propionate, ethoxyethoxy propionate, or any combination thereof.

In the photoresist composition, according to some implementations, the solvent may be included in a remaining amount excluding the contents of the main components including the organometallic compound and a photosensitive additive. In some implementations, the solvent may be included in an amount in a range from about 70 wt % to about 99.8 wt % based on the total weight of the photoresist composition, but is not limited thereto.

In some implementations, when the photoresist composition according to the embodiments includes the PAG as the photoinitiator, the photoresist composition may further include a basic quencher. The basic quencher may include a compound capable of trapping acids in the non-exposed region when acids generated from the PAG included in the photoresist composition according to the embodiments or acids generated from other photodegradable compounds diffuse into the non-exposed region. Because the basic quencher is included in the photoresist composition according to some implementations, the diffusion rate of acid in the photoresist film obtained from the photoresist composition may be suppressed.

In some implementations, the basic quencher may include a primary aliphatic amine, a secondary aliphatic amine, a tertiary aliphatic amine, an aromatic amine, an amine including a heteroaromatic ring, a nitrogen-including compound having a carboxyl group, a nitrogen-including compound having a sulfonyl group, a nitrogen-including compound having a hydroxyl group, a nitrogen-including compound having a hydroxyphenyl group, an alcoholic nitrogen-including compound, amides, imides, carbamates, or ammonium salts. For example, the basic quencher may include triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl) aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or any combination thereof, but is not limited to the examples above.

In some implementations, the basic quencher may include a photobase generator. The photobase generator may generate a base by absorbing active energy rays through light irradiation and decomposing its chemical structure. Accordingly, when a partial region of a photoresist film formed from a photoresist composition including a basic quencher including a photobase generator is exposed, the photobase generator traps acid in the exposed region of the photoresist film, and thus, the sensitivity in the exposure region may be adjusted and the diffusion of acid from the exposed region to the non-exposed region may be suppressed. Accordingly, a metal structure network consisting of a metal oxide including the central metal may be formed selectively only in the exposed region of the photoresist film, and thus, an adverse effect due to undesired diffusion of the acid, for example, the problem such as deterioration of critical dimension (CD) distribution at edges of the photoresist pattern obtained after a development process may be prevented.

A material constituting the photobase generator is not particularly limited as long as it generates a base by light irradiation. In some implementations, the photobase generator may be comprised of a non-ionic photobase generator. In some implementations, the photobase generator may include an ionic photobase generator.

In some implementations, the photobase generator may include a carboxylate or sulfonate salt of a photodecomposable cation. For example, the photodecomposable cation included in the photobase generator may be a sulfonium cation. The sulfonium cation may include a substituted or unsubstituted C1 to C12 alkyl group, a substituted or unsubstituted C3 to C12 cycloalkyl group, a C6 to C30 aryl group, or a C2 to C30 heteroaryl group. The alkyl group, the cycloalkyl group, the aryl group, and the heteroaryl group may include at least one hetero atom selected from O atoms, S atoms, and N atoms. For example, the sulfonium cation may include, but is limited to, a phenyl group, a cyclopentyl group, a cyclohexyl group, an adamantyl group, a methyl group, an ethyl group, a propyl group, a butyl group, a t-butyl group, or an isopropyl group.

The photodecomposable cation included in the photobase generator may form a complex with an anion of C1 to C20 carboxylic acid. The carboxylic acid may be, for example, formic acid, acetic acid, propionic acid, tartaric acid, succinic acid, cyclohexanecarboxylic acid, benzoic acid, or salicylic acid, but is not limited thereto.

In some implementations, triphenylsulfonium heptafluorobutyric acid, or triphenyl sulfonium hexafluoroantimonate (TPS-SbF6) may be used as the photobase generator, but it is not limited thereto.

In the photoresist composition, according to some implementations, the basic quencher may be used alone, or a mixture of two or more types of radical quenchers may be used. The basic quencher may be included in a molar ratio range from about 0.01 to about 0.5 based on the total content of the organometallic compound, but is not limited thereto.

In some implementations, when the PRG is included as the photoinitiator in the photoresist composition, the photoresist composition may further include a radical quencher capable of trapping radicals.

In some implementations, the radical quencher may include a quinone type free radical, or a nitroxide (IUPAC name: aminoxyl) free radical.

The quinone type free radical may include p-benzoquinone, 1,4-dihydroxybenzene, 4-methoxyphenol, hydroquinone monomethyl ether, hydroquinone monophenyl ether, mono-t-butyl hydroquinone (MTBHQ), di-t-butyl hydroquinone, di-t-amyl hydroquinone, toluhydroquinone, p-benzoquinone dioxime, 2,6-dichloro-1,4-benzoquinone, 2,3,5,6-tetramethyl-1,4-benzoquinone, 2,5-dichloro-3,6-dihydroxy-p-benzoquinone, methyl-p-benzoquinone, 6-anilinoquinoline-5,8-quinone, pyrroloquinoline quinone, 2-allyl-6-methoxybenzo-1,4-quinone, or any combination thereof, but is not limited thereto.

The nitroxide free radicals may include di-tert-butyl nitroxide (DTBN), 2,2,6,6-tetramethyl-1-peperidine 1-oxyl (TEMPO), 4-oxo-2, 2, 6, 6-tetramethyl-1-peperidine 1-oxyl(oxo TEMPO), 1,1,3,3-tetraethylisoindolin-N-oxyl, N-tert-butyl-N-[1-(diethoxyphosphoryl)-2,2-dimethylpropyl]aminoxyl (SGI), N-tert-butyl-N-(2-methyl-1-phenylpropyl)aminoxyl (TIPNO), or combinations thereof, but are not limited thereto.

When performing a photolithography process using a photoresist composition, according to some implementations, radicals generated from the PRG are quenched by the radical quencher in the exposed region of the photoresist film obtained from the photoresist composition, and thus, the sensitivity adjustment in the exposed region may be possible, and radicals flowing from the exposed region to the non-exposed region may be quenched by the radical quencher. Accordingly, a network consisting of a metal oxide that selectively includes the central metal in the exposed region may be formed, and adverse effects due to unwanted diffusion of the radicals, for example, problems such as the deterioration of CD distribution at edges of the photoresist pattern obtained after a development process may be prevented.

In the photoresist composition, according to some implementations, the radical quencher may be used alone, or a mixture of two or more types of radical quenchers may be used. The radical quencher may be included in a molar ratio range from about 0.01 to about 0.5 based on the total content of the organometallic compound, but is not limited thereto.

In some implementations, the photoresist composition may further include at least one selected from a leveling agent, a surfactant, a dispersant, a moisture absorbent, and a coupling agent.

The leveling agent improves coating flatness when coating the photoresist composition on a substrate, and a known leveling agent commercially available may be used.

The surfactant may improve coating uniformity and wettability of the photoresist composition. In example embodiments, the surfactant may include a sulfuric acid ester salt, a sulfonate salt, a phosphoric acid ester, soap, an amine salt, a quaternary ammonium salt, polyethylene glycol, an alkylphenolethylene oxide adduct, a polyhydric alcohol, a nitrogen-including vinyl polymer, or any combination thereof, but is not limited thereto. For example, the surfactant may include alkylbenzenesulfonate, alkylpyridinium salt, polyethylene glycol, or quaternary ammonium salt. When the photoresist composition includes the surfactant, the surfactant may be included in an amount range from about 0.001 wt % to about 3 wt % based on the total weight of the photoresist composition.

The dispersing agent may ensure that each component constituting the photoresist composition is uniformly dispersed within the photoresist composition. In some implementations, the dispersant may include epoxy resin, polyvinyl alcohol, polyvinyl butyral, polyvinylpyrrolidone, glucose, sodium dodecyl sulfate, sodium citrate, oleic acid, linoleic acid, or any combination thereof, but is not limited thereto. When the photoresist composition includes the dispersant, the dispersant may be included in an amount range from about 0.001 wt % to about 5 wt % based on the total weight of the photoresist composition.

The moisture absorbent may prevent adverse effects caused by moisture in the photoresist composition. In some implementations, the moisture absorbent may include polyoxyethylene nonylphenolether, polyethylene glycol, polypropylene glycol, polyacrylamide, or any combination thereof, but is not limited thereto. When the photoresist composition includes the moisture absorbent, the moisture absorbent may be included in an amount range from about 0.001 wt % to about 10 wt % based on the total weight of the photoresist composition.

The coupling agent may improve adhesion to a lower film when coating the photoresist composition on the lower film. In some implementations, the coupling agent may include a silane coupling agent. The silane coupling agent may include vinyltrimethoxysilane, vinyltriethoxysilane, vinyl trichlorosilane, vinyltris(β-methoxyethoxy) silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy [3-(phenylamino) propyl]silane, but is not limited thereto. When the photoresist composition includes the coupling agent, the coupling agent may be included in an amount range from about 0.001 wt % to about 5 wt % based on the total weight of the photoresist composition.

When a photoresist film obtained from a photoresist composition including the organometallic compound, according to some implementations, is exposed to light, the organometallic compound may absorb the light, and some of organic ligands in the organometallic compound may break bonds with the central metal and may dissociate. For example, when the organometallic compound is exposed to any one light selected from a KrF excimer laser (248 nm), an ArF excimer laser (193 nm), an F2 excimer laser (157 nm), and an EUV laser (13.5 nm), the organometallic compound may absorb the light, and some of the organic ligands may break bonds with the central metal and dissociate.

In some implementations, when a photoresist film obtained from a photoresist composition including an organometallic compound according to example embodiments is exposed to light, the ylide ligand may decompose.

Specifically, due to the exposure of the photoresist film, secondary electrons may be generated, and due to the secondary electrons, the bond between the first atom with a −1 formal charge and the second atom with a +1 formal charge of the ylide ligand is broken, and the second atom and the secondary electron may combine. As a result, a functional group including the second atom of the ylide ligand may be separated from the organometallic compound.

Alternatively, radicals may be generated by the photoinitiator included in the photoresist composition, and due to the breakage of bonds of other organic ligands around the ylide ligand with the central metal, the radicals may be ligand radicals having unpaired electrons. The bond between the first atom with a formal charge of −1 and the second atom with a formal charge of +1 of the ylide ligand is decomposed by the radical generated by the photoinitiator or the ligand radical, and a functional group including the second atom, which is desorbed by the decomposition of the bond between the first atom and the second atom, may combine with the radical generated by the photoinitiator or the ligand radical.

Accordingly, the first atom of the ylide ligand may be a radical having an unpaired electron. Thereafter, the first atom of the ylide ligand in a radical state may break the hydrogen bond with other surrounding atoms that have a lower bonding force than the bonding force between the first atom of the ylide ligand and hydrogen, and may bond with hydrogen. For example, the other surrounding atom having a bonding strength less than a bonding strength between the first atom of the ylide ligand and hydrogen may be an atom included in an alkyl group of another organic ligand surrounding the ylide ligand. Through the bond between the first atom of the ylide ligand and hydrogen, the coordination bond between the first atom of the ylide ligand and the central metal may be weakened, and thus, the desorption of the first atom of the ylide ligand from the central metal may easily occur. After the exposure process of the photoresist film, a desorption reaction of the first atom of the ylide ligand may be induced by a subsequent bake process, and as a result, the coordination bond between the first atom of the ylide ligand and the central metal may be weakened, and thus, the desorption reaction of the first atom may occur relatively easily.

Thereafter, a hydroxyl (OH) functional group may be generated at the site where the first atom of the ylide ligand is desorbed. A condensation reaction of the hydroxyl (OH) functional group may be induced by the baking process, and a cross-linking structure including a plurality of metals (M), for example, a M-O-M cross-linked structures may be formed through a cross-linking reaction of organic ligands of adjacent organometallic compounds. In present disclosure, the cross-linked structure may be referred to as a metal structure network.

For example, when a photoresist film obtained from a photoresist composition including the organometallic compound including the above-described formula 1 is exposed, B¹¹ may be decomposed. The decomposition reaction of B¹¹ may be expressed in Reaction Formula 1 or Reaction Formula 2 below. The Reaction Formula 1 or Reaction Formula 2 below shows the decomposition reaction when B¹¹ is the above-described R³¹—C(═O)—N⁻([C₅H₅NH]⁺)—*.

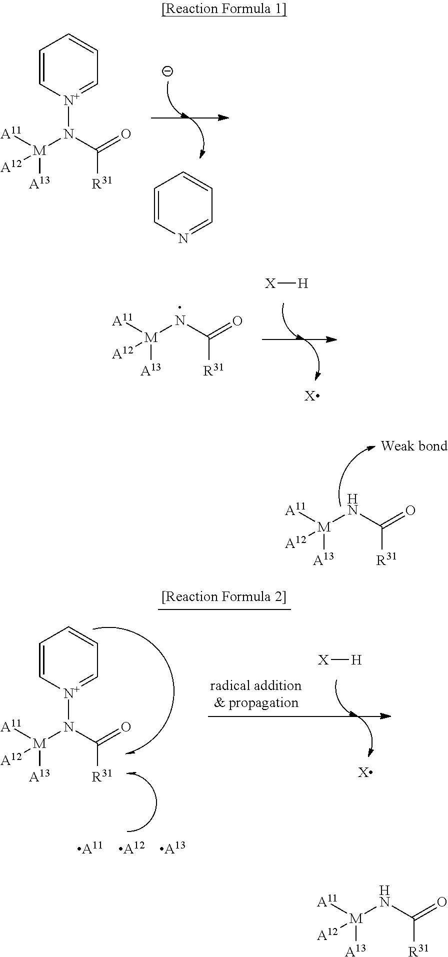

In Reaction Formula 1 and Reaction Formula 2, X may be a photoinitiator, for example, may be a material having an X—H bond weaker than an N—H bond. For example, X may include carbon (C), silicon (Si), sulfur(S), or phosphorus (P) of a C1 to C20 alkyl group.

In some implementations, in a process in which the first atom of the ylide ligand in a radical state breaks a hydrogen bond with other surrounding atoms having a less bonding force than the bonding force between the first atom of the ylide ligand and hydrogen and forms a bond with the desorbed hydrogen, other atoms in the surrounding region may become radicals. Thereafter, the other atoms in the radical state may cause a chain reaction, that is, a chain reaction of decomposition of the ylide ligand. For example, the other atoms in the radical state may break the bond between the first atom of the ylide ligand and the second atom, and bond with the second atom of the ylide ligand. As a result, the first atom of the ylide ligand may become a radical with an unpaired electron, and other surrounding atoms again may become radicals, and thus, the above-described chain reaction of decomposition of the ylide ligand may occur again.

For example, when a photoresist film obtained from a photoresist composition including an organometallic compound having the above-described Formula 1 is exposed to light, B¹¹ is decomposed, and a chain decomposition reaction may occur due to the radicals (in other words, the first atom in a radical state that occurs when the bond between the first atom of B¹¹ with a formal charge of −1 and the second atom with a formal charge of +1 is broken) generated when B¹¹ is decomposed. The chain reaction caused by the radical may be expressed in Reaction Formula 3 below. Reaction Formula 3 below shows a chain decomposition reaction when B¹¹ is the above-described R³¹—C(═O)—N⁻([C₅H₅NH]⁺)—*.

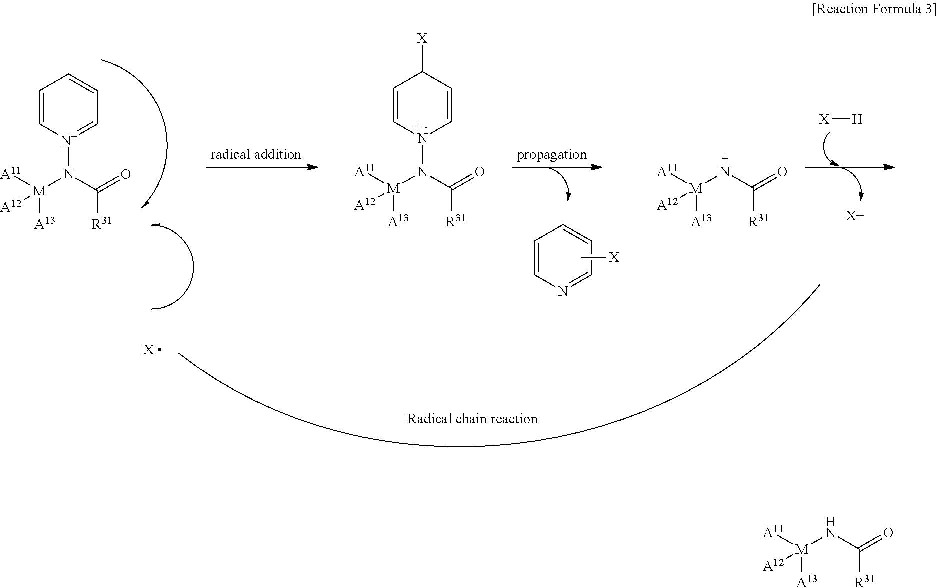

In Reaction Formula 3, X may be a photoinitiator, for example, and may be a material having a X—H bond weaker than N—H bond. For example, X may include carbon (C), silicon (Si), sulfur(S), or phosphorus (P) of a C1 to C20 alkyl group.

The photoresist composition, according to some implementations, may include an organic ligand including an ylide group and constituting an organometallic compound by bonding with a central metal or an organic ligand precursor including an ylide group capable of forming a coordination complex with the central metal. In the exposure process, because a chain decomposition reaction is induced by using a decomposition reaction of the ylide ligand and radicals generated by the decomposition reaction, during storage and/or transportation of the photoresist composition or during a process of manufacturing an integrated circuit device that uses the photoresist composition, unwanted changes over time caused by light or moisture in the air may be prevented, and accordingly, by suppressing a reaction in which the central metal reacts with moisture to generate a hydroxy group (OH group), the temporal stability of the photoresist composition may be secured, and the process stability of manufacturing an integrated circuit device that uses the photoresist composition may be secured.

In addition, due to the high reactivity and short lifespan of the radical generated by the decomposition of the ylide ligand, the decomposition reaction of other ylide ligands in the non-exposed area, which may occur when the radical generated by the decomposition of the ylide ligand penetrates into the non-exposed region, may be relatively low, and thus, the exposure sensitivity in the exposed region of the photoresist film may be increased. Accordingly, high resolution and improved sensitivity may be provided in the photolithography process, and the dimensional precision of a pattern to be formed may be improved by preventing CD distribution deterioration of the pattern obtained by the photolithography process.

Hereinafter, a method of manufacturing an integrated circuit device using a photoresist composition according to embodiments is described using specific examples.

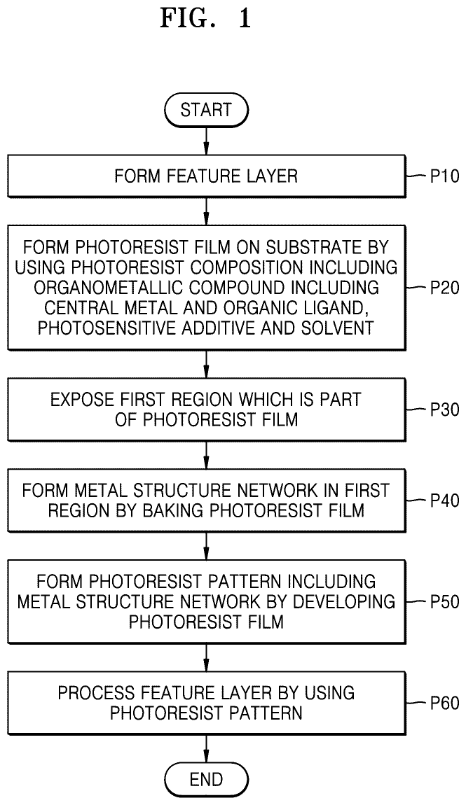

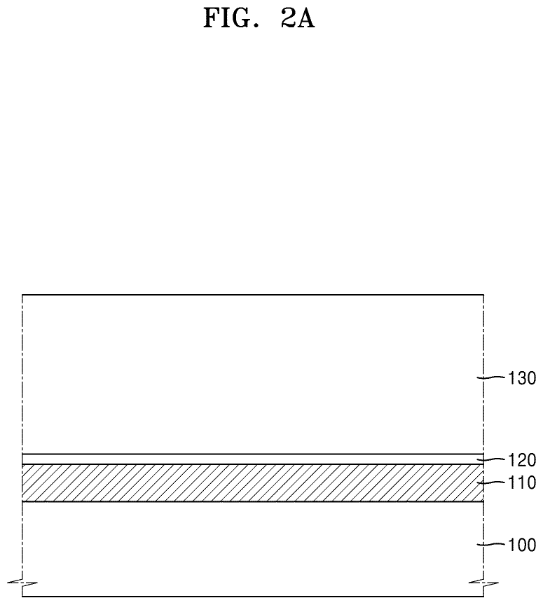

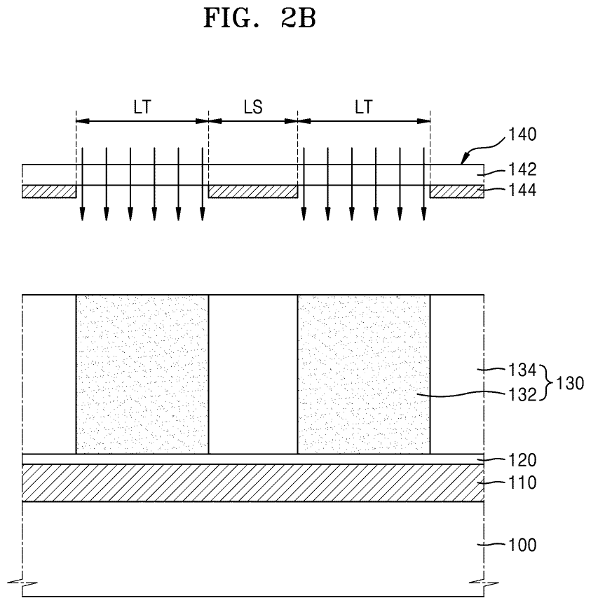

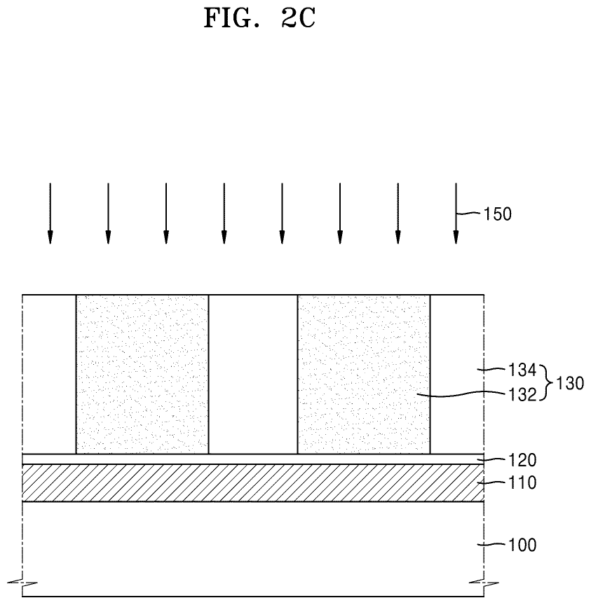

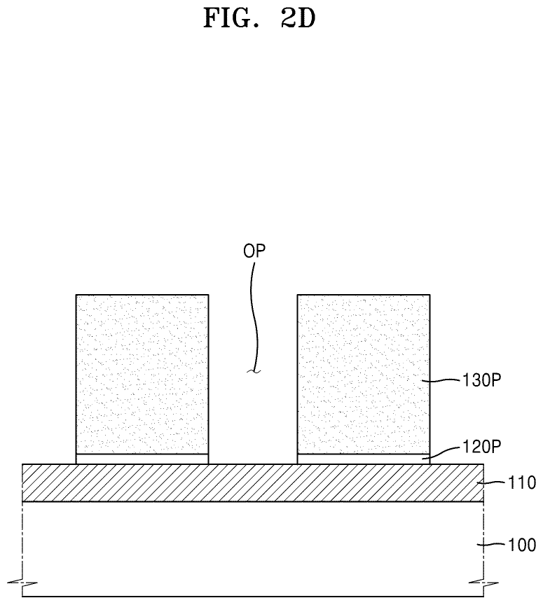

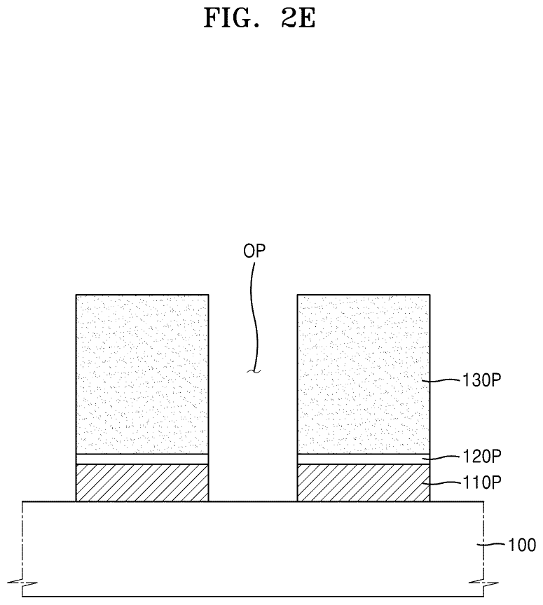

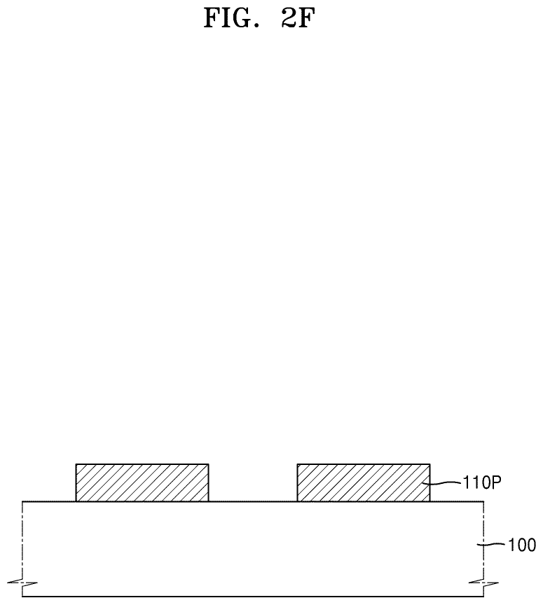

FIG. 1 is a flowchart illustrating an example of a method of manufacturing an integrated circuit device according to some implementations. FIGS. 2A-2F are cross-sectional views showing in sequence to explain an example of a method of manufacturing an integrated circuit device according to some implementations.

In FIGS. 1 and 2A, in process P10, a feature layer 110 may be formed on a substrate 100. Thereafter, in process P20, a photoresist film 130 may be formed on the feature layer 110 using a photoresist composition according to embodiments. A more detailed configuration of the photoresist composition is as described above.

The substrate 100 may include a semiconductor substrate. The feature layer 110 may include an insulating film, a conductive film, or a semiconductor film. For example, the feature layer 110 may include a metal, an alloy, metal carbide, metal nitride, metal oxynitride, metal oxycarbide, semiconductor, polysilicon, oxide, nitride, oxynitride, or any combination thereof, but is not limited thereto.

In some implementations, as illustrated in FIG. 2A, a lower film 120 may be formed on the feature layer 110 before forming a photoresist film 130 on the feature layer 110. In this case, the photoresist film 130 may be formed on the lower film 120. The lower film 120 may prevent the photoresist film 130 from receiving adverse effects from the feature layer 110. In some implementations, the lower film 120 may include an organic or inorganic anti-reflective coating (ARC) material for a KrF excimer laser, an ArF excimer laser, an EUV laser, or any arbitrary light source. In some implementations, the lower film 120 may include a bottom anti-reflective coating (BARC) film or a developable bottom anti-reflective coating (DBARC) film. In some implementations, the lower film 120 may include an organic component having a light absorption structure. The light absorption structure may be, for example, a hydrocarbon compound having one or more benzene rings or a structure in which benzene rings are fused. The lower film 120 may be formed to have a thickness in a range from about 1 nm to about 100 nm, but is not limited thereto. In example embodiments, the bottom film 120 may be omitted.

To form the photoresist film 130, the photoresist composition, according to some implementations, may be coated on the lower film 120 and then heat treated. The coating may be performed by methods such as spin coating, spray coating, dip coating, etc. The process of heat treating the photoresist composition may be performed at a temperature in a range from about 80° C. to about 300° C. for about 10 seconds to about 100 seconds, but is not limited thereto. A thickness of the photoresist film 130 may be tens to hundreds of times the thickness of the lower film 120. The photoresist film 130 may be formed to have a thickness in a range from about 10 nm to about 1 μm, but is not limited thereto.

In some implementations, the photoresist composition for forming the photoresist film 130 includes an organometallic compound, and the organometallic compound may include a central metal and an ylide ligand coordinated with the central metal.

In some implementations, when the photoresist composition for forming the photoresist film 130 further includes an ylide ligand precursor, after the photoresist film 130 is formed or during the photoresist film 130 is formed, a modified organometallic compound may be formed by binding the ylide ligand to the central metal of the organometallic compound through a ligand substitution reaction between the organometallic compound and the ylide ligand precursor in the photoresist film 130.

In FIGS. 1 and 2B, in process P30, a first region 132, which is parts of the photoresist film 130, may be exposed. As a result, the decomposition reaction of the ylide ligand as described above may be induced in the organometallic compound included in the photoresist film 130 in the first region 132.

Specifically, when the first region 132, which is a part of the photoresist film 130, is exposed according to process P30 of FIG. 1, the bond between a first atom having a formal charge of −1 of the ylide ligand and a second atom having a formal charge of +1 may be broken in the first region 132, and the bond between the central atom and the first atom may be weakened, and thus, a desorption reaction in which the first atom is detached from the central atom for generating a hydroxy group (OH) may easily occur in a subsequent process.

Therefore, after the photoresist film 130 is formed, an undesired reaction due to light or moisture in the photoresist film 130, for example, a reaction in which the central metals included in the photoresist film 130 react with moisture to generate a hydroxy group (OH group) may be suppressed until the subsequent exposure process is performed, thereby ensuring the stability of the photoresist composition over time.

In addition, due to the high reactivity and short lifespan of the radical generated by the decomposition of the ylide ligand, the decomposition reaction of other ylide ligands in the non-exposed area, which may occur when the radical generated by the decomposition of the ylide ligand penetrates into the non-exposed region, may be relatively low, and thus, the exposure sensitivity in the exposed region of the photoresist film may be increased. Accordingly, high resolution and improved sensitivity may be provided in the photolithography process, and the dimensional precision of a pattern to be formed may be improved by preventing CD distribution deterioration of the pattern obtained by the photolithography process.

In some implementations, when the photoresist film 130 includes a photoinitiator, when the first region 132, which is a part of the photoresist film 130, is exposed according to process P30 of FIG. 1, an acid or radical may be generated from the photoinitiator in the first region 132. The photoinitiator may include a PAG configured to generate acid by light, a PRG configured to generate radicals by light, or any combination of the PAG and the PRG. Accordingly, while the first region 132 of the photoresist film 130 is exposed according to process P30 of FIG. 1, the photoinitiator included in the photoresist film 130 in the first region 132 may generate acid and/or radicals by absorbing light.

In some implementations, to expose the first region 132 of the photoresist film 130, a photomask 140 having a plurality of light shielding areas LS and a plurality of light transmitting areas LT is aligned at a predetermined position on the photoresist film 130, and the first region 132 of the photoresist film 130 may be exposed through the plurality of light transmitting areas LT of the photomask 140. To expose the first region 132 of the photoresist film 130, a KrF excimer laser (248 nm), an ArF excimer laser (193 nm), a F2 excimer laser (157 nm), or an EUV laser (13.5 nm) may be used.

In some implementations, the photomask 140 may include a transparent substrate 142 and a plurality of light blocking patterns 144 formed in the plurality of light blocking areas LS on the transparent substrate 142. The transparent substrate 142 may include quartz. The plurality of light blocking patterns 144 may include chrome (Cr). The plurality of light transmitting areas LT may be defined by the plurality of light blocking patterns 144. According to the present inventive concept, to expose the first region 132 of the photoresist film 130, a reflective photomask (not shown) for EUV exposure may be used instead of the photomask 140.

In FIGS. 1 and 2C, a bake process may be performed by applying heat 150 to the photoresist film 130 including the first region 132 exposed in process P40.

The bake process may be performed at a temperature in a range from about 50° C. to about 400° C. for about 10 seconds to about 150 seconds. For example, the bake process may be performed at a temperature in a range from about 150° C. to about 250° C. for about 60 seconds to about 120 seconds, but is not limited thereto.

In some implementations, in the first region 132, because the bond between the central metal and the first atom having a formal charge of −1 of the ylide ligand is weakened through a decomposition reaction of the ylide ligand, while performing the bake process of the photoresist film 130, the bond between the central metal and the first atom of the ylide ligand may be relatively easily broken. Accordingly, the first atom of the ylide ligand may be desorbed from the central metal, and a condensation reaction of the hydroxyl (OH) functional group is induced at the site where the first atom of the ylide ligand is desorbed, thus, a dense metal structure network may be formed.

In some implementations, when the photoresist film 130 includes a photoinitiator, while performing the bake process of the photoresist film 130, in the first region 132, a desorption reaction of the organic ligand may be induced in the organometallic compound using an acid or a radical generated from the photoinitiator, and a condensation reaction of the hydroxyl (OH) functional group generated at the site where the organic ligand is desorbed is induced, and thus, a dense metal structure network may be formed.

On the other hand, a metal structure network is not formed in the second region 134, which is a non-exposed region of the photoresist film 130, and accordingly, the difference in solubility in a developer between the first region 132 and the second region 134 of the photoresist film 130 may increase.

In FIGS. 1 and 2D, in process P50, the second region 134 of the photoresist film 130 may be removed by developing the photoresist film 130 using a developer. As a result, a photoresist pattern 130P including the metal structure network formed in the exposed first region 132 of the photoresist film 130 may be formed.

The photoresist pattern 130P may include a plurality of openings OP. After the photoresist pattern 130P is formed, a lower pattern 120P may be formed by removing portions of the lower film 120 exposed through the plurality of openings OP.

In some implementations, the development of the photoresist film 130 may be performed using a negative-tone development (NTD) process.

In some implementations, a developer including an organic solvent may be used to develop the photoresist film 130. For example, the developer may include ketones such as methyl ethyl ketone, acetone, cyclohexanone, 2-heptanone, etc.; alcohols such as 4-methyl-2-propanol, 1-butanol, isopropanol, 1-propanol, methanol, etc.; esters such as propylene glycol monomethyl ether acetate, ethyl acetate, ethyl lactate, n-butyl acetate, butyrolactone, etc.; aromatic compounds such as benzene, xylene, toluene, etc.; or any combination thereof, but is not limited thereto.

As explained with reference to FIG. 2C, as the difference in solubility in the developer between the exposed first region 132 and the non-exposed second region 134 of the photoresist film 130 increases, while the second region 134 is removed by developing the photoresist film 130 in the process of 2D, the first region 132 may remain without being removed. Accordingly, after developing the photoresist film 130, residual defects such as footing do not occur, and a vertical sidewall profile may be obtained in the photoresist pattern 130P. In this way, the sidewall profile of the photoresist pattern 130P is improved, and thus, when processing the feature layer 110 using the photoresist pattern 130P, a critical dimension of an intended processing area in the feature layer 110 may be precisely adjusted.

In some implementations, after forming the photoresist pattern 130P by developing the photoresist film 130, a process of hard bake the obtained resultant product may further be performed. Through the hard bake process, unnecessary substances such as developer remaining on the resultant product on which the photoresist pattern 130P is formed may be removed. In addition, while performing the bake process according to process P40 of FIG. 1 with reference to FIG. 2C, if the desorption reaction of the organic ligand in the organometallic compound and the resulting additional condensation reaction do not proceed sufficiently, additional reaction of the unreacted parts may be induced through the hard bake process. Accordingly, through the hard bake process, the hardness of the photoresist pattern 130P may further be strengthened.

The hard bake process may be performed at a temperature in a range from about 50° C. to about 400° C. for about 10 seconds to about 150 seconds. For example, the hard bake process may be performed at a temperature in a range from about 150° C. to about 250° C. for about 60 seconds to about 120 seconds, but is not limited thereto.

In FIGS. 1 and 2E, in process P60, the feature layer 110 in the resultant product of FIG. 2D may be processed using the photoresist pattern 130P.

In order to process the feature layer 110, various processes, such as a process of etching the feature layer 110 exposed through the opening OP of the photoresist pattern 130P, a process of implanting impurity ions into the feature layer 110, a process of forming an additional film on the feature layer 110 through the opening (OP), and a process of deforming a part of the feature layer 110 through the opening (OP), etc. In FIG. 2E, as an example process for processing the feature layer 110, a case of forming a feature pattern 110P by etching the feature layer 110 exposed through the opening OP is illustrated, but the present disclosure is not limited thereto.

In some implementations, in the process described with reference to FIG. 2A, the process of forming the feature layer 110 may be omitted, and in this case, instead of the process P60 of FIG. 1 and the process described with reference to FIG. 2E, the substrate 100 may be processed using the pattern 130P. For example, various processes such as a process of etching a part of the substrate 100 using the photoresist pattern 130P, a process of implanting impurity ions into a partial area of the substrate 100, a process of forming an additional film on the substrate 100 through the opening (OP), a process of deforming a portion of the substrate 100 through the opening (OP), etc.

In FIG. 2F, the photoresist pattern 130P and the lower pattern 120P remaining on the feature pattern 110P may be removed from the resultant product of FIG. 2E. An ashing process and a stripping process may be used to remove the photoresist pattern 130P and the lower pattern 120P.

According to the manufacturing method of an integrated circuit device according to the present disclosure described with reference to FIGS. 1 and 2A-2F, the difference in solubility in the developer increases between the exposed and non-exposed areas of the photoresist film 130 obtained using the photoresist composition according to the present inventive concept, and the CD distribution in the photoresist pattern 130P may be improved. Accordingly, when performing a subsequent process on the feature layer 110 and/or the substrate 100 using the photoresist pattern 130P, the dimensional precision of the feature layer 110 and/or the substrate 100 may be improved by precisely controlling critical dimensions of processing regions or patterns to be formed on the feature layer 110 and/or substrate 100. In addition, the CD distribution of patterns to be implemented on the substrate 100 may be uniformly controlled, and the productivity of a manufacturing process of the integrated circuit device may be improved.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A photoresist composition comprising:
an organometallic compound including a central metal and at least one organic ligand bonded to the central metal; and
a solvent,
wherein the at least one organic ligand included in the organometallic compound includes an ylide group including an atom with a formal charge of −1 coordinately bonded to the central metal and a hetero atom with a formal charge of +1 bonded to the atom with a formal charge of −1.

2. The photoresist composition of claim 1, wherein the hetero atom of the at least one organic ligand is one of nitrogen (N), sulfur(S), and phosphorus (P).

3. The photoresist composition of claim 1, wherein the organometallic compound is represented by:
M(A¹¹)ₐ(A¹²)_{b}(A¹³)_{c}(B¹¹)_{d},
where M represents Sn, Sb, In, Bi, Ag, Te, Au, Pb, Zn, Ti, Hf, Zr, Al, V, Cr, Co, Ni, Cu, Ga, Mn, Sr, W, Cd, Mo, Ta, Nb, Cs, Ba, La, Ce, or Fe,
A¹¹, A¹², and A¹³ each represent a substituted or unsubstituted C1 to C30 aliphatic hydrocarbon group or a substituted or unsubstituted C6 to C30 aromatic hydrocarbon group, covalently or coordinately bonded to the M,
B¹¹ represents: a C1 to C30 aliphatic hydrocarbon group including a first atom with a formal charge of −1 that is coordinately bonded to M and a second atom that is a hetero atom with a formal charge of +1 bonded to the first atom; or a substituted or unsubstituted C6 to C30 aromatic hydrocarbon group including the first atom and the second atom, and
a, b, c, and d are each independently an integer greater than 0 and less than or equal to 4, and a+b+c+d is less than or equal to 4.

4. The photoresist composition of claim 3, wherein at least one of A¹¹, A¹², or A¹³ is a substituted or unsubstituted C1 to C30 aliphatic hydrocarbon group covalently bonded to M, or a substituted or unsubstituted C6 to C30 aromatic hydrocarbon group covalently bonded to M.

5. The photoresist composition of claim 3, wherein at least one of A¹¹, A¹², or A¹³ includes at least one hetero atom, and is a substituted or unsubstituted C1 to C30 aliphatic hydrocarbon group coordinated to M, or a substituted or unsubstituted C6 to C30 aromatic hydrocarbon group.

6. The photoresist composition of claim 3, wherein B¹¹ is a ylide group including pyridinium, [C₅H₅NH]⁺.

7. The photoresist composition of claim 3, wherein B¹¹ is R³¹—C(═O)—N⁻([C₅H₅NH]⁺)—*, R³²—S(═O)₂—N⁻([C₅H₅NH]⁺)—*, R³³—C(═O)—C⁻([C₅H₅NH]⁺)—*, or [C₅H₅NH]⁺—O⁻—*, and
wherein * is a binding site with M, and R³¹, R³², and R³³ are each hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

8. The photoresist composition of claim 3, wherein B¹¹ is R³⁴-Ht⁺(R³⁵)(R³⁶)—C⁻(R³⁷)—*, and
wherein * is a binding site with M, Ht is a hetero atom, and R³⁴, R³⁵, R³⁶, and R³⁷ are each hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.)

9. The photoresist composition of claim 1, wherein the at least one organic ligand includes at least one structure selected from following structures: 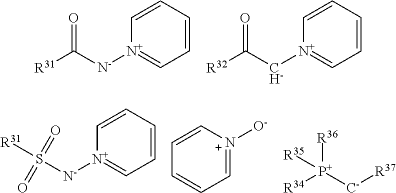
where R³¹, R³², R³³, R³⁴, R³⁵, R³⁶, and R³⁷ are each hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

10. The photoresist composition of claim 1, wherein the at least one organic ligand includes at least one structure selected from following structures: 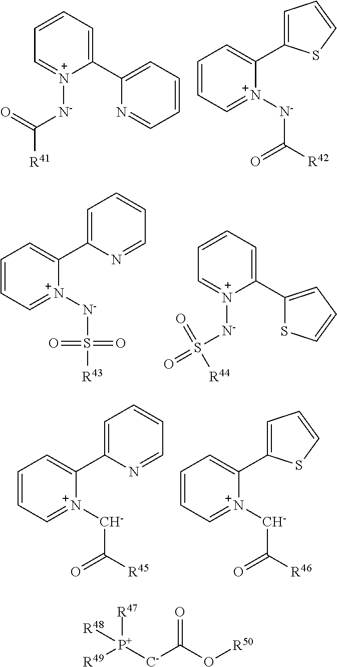
where R⁴¹, R⁴², R⁴³, R⁴⁴, R⁴⁵, R⁴⁶, R⁴⁷, R⁴⁸, R⁴⁹, and R⁵⁰ are each hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

11. The photoresist composition of claim 1, wherein the photoresist composition further includes an organic ligand precursor, and
wherein the organic ligand precursor includes a ylide group including:
a first atom with a formal charge of −1 capable of a ligand substitution reaction with the at least one organic ligand bonded to the central metal; and
a second atom that is a heteroatom with a +1 formal charge bonded to the first atom.

12. The photoresist composition of claim 1, wherein the organometallic compound is expressed as MR¹¹R¹²X¹³B¹¹ or MR¹¹X¹²X¹³B¹¹,
where M is a central metal,
R¹¹ and R¹² are each a substituted or unsubstituted C1 to C30 aliphatic hydrocarbon group or a substituted or unsubstituted C6 to C30 aromatic hydrocarbon group covalently bonded to M,
X¹² and X¹³ are each a substituted or unsubstituted C1 to C30 aliphatic hydrocarbon group or a substituted or unsubstituted C6 to C30 aromatic hydrocarbon group, including at least one hetero atom and coordinately bonded to M, and
B¹¹ is an ylide group that coordinates with M.

13. A photoresist composition comprising:
an organometallic compound including a central metal and a plurality of organic ligands bonded to the central metal;
an organic ligand precursor; and
a solvent,
wherein the plurality of organic ligands included in the organometallic compound is a substituted or unsubstituted C1 to C30 aliphatic hydrocarbon group, or a substituted or unsubstituted C6 to C30 aromatic hydrocarbon group covalently or coordinately bonded to the central metal, and
wherein the organic ligand precursor is a C1 to C30 aliphatic hydrocarbon group including a first atom with a formal charge of −1 capable of a ligand substitution reaction with at least one of the plurality of organic ligands bonded to the central metal, and a second atom that is a hetero atom with a formal charge of +1 bonded to the first atom, or a substituted or unsubstituted C6 to C30 aromatic hydrocarbon group including the first atom and the second atom.

14. The photoresist composition of claim 13, wherein the organic ligand precursor includes pyridinium, [C₅H₅NH]⁺.

15. The photoresist composition of claim 13, wherein the organic ligand precursor includes:
R⁵¹—C(═O)—N⁻([C₅H₅NH]⁺), R⁵²—S(═O)₂—N⁻([C₅H₅NH]⁺), R⁵³—C(═O)—C⁻([C₅H₅NH]⁺), or [C₅H₅NH]⁺—O⁻,
where R⁵¹, R⁵², and R⁵³ are each hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

16. The photoresist composition of claim 13, wherein the organic ligand precursor includes R⁵⁴-Ht⁺(R⁵⁵)(R⁵⁶)—C⁻(R⁵⁷),
where Ht is a hetero atom, and
R⁵⁴, R⁵⁵, R⁵⁶, and R⁵⁷ are each hydrogen, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C30 cycloalkyl group, a substituted or unsubstituted C1 to C30 alkoxy group, a substituted or unsubstituted C6 to C30 aryl group, a substituted or unsubstituted C2 to C30 heteroaryl group, a substituted or unsubstituted C7 to C30 arylalkyl group, or a substituted or unsubstituted phenyl group.

17. A method of manufacturing an integrated circuit device, the method comprising:
forming a photoresist film on a substrate by using a photoresist composition including a central metal, an organometallic compound including a plurality of organic ligands bonded to the central metal, and a solvent;
exposing a first region that is part of the photoresist film;
forming a metal structure network in the first region by inducing a desorption reaction of at least part of the plurality of organic ligands from the organometallic compound in the first region by baking the photoresist film including the exposed first region, and by inducing a condensation reaction of a hydroxyl (OH) functional group generated at a site where some of the plurality of organic ligands among the organometallic compound are desorbed; and
forming a photoresist pattern including the metal structure network by developing the photoresist film on which the metal structure network is formed,
wherein, in the forming of the photoresist film, at least one of the plurality of organic ligands includes an ylide group including a first atom and a second atom,
wherein the first atom has a formal charge of −1 and is coordinated to the central metal, and
wherein the second atom is a heteroatom with a formal charge of +1 and is bonded to the first atom.

18. The method of claim 17, wherein, in the exposing of the first region, the bond between the first atom and the second atom is broken in the ylide group of the organic ligand.

19. The method of claim 17, wherein, in the exposing of the first region, in the ylide group of the organic ligand, the first atom becomes a radical with an unpaired electron.

20. The method of claim 17, wherein the organic ligand includes a ylide group including pyridinium [C₅H₅NH]⁺.
